(19) United States
(12) Patent Application Publication
(10) Pub. No.: US 2025/0105071 A1
(43) Pub. Date: Mar. 27, 2025

(54) Packaged Integrated Circuit Device Having A Deformable Lid, And Associated Methods

(71) Applicant: NXP USA, Inc., Austin, TX (US)

(72) Inventor: Jinquan Wang, Tianjin (CN)

(21) Appl. No.: 18/891,287

(22) Filed: Sep. 20, 2024

(30) Foreign Application Priority Data
Sep. 27, 2023 (CN) 202311265937.7

(51) Int. Cl. H01L 23/06; H01L 21/48; H01L 23/053

(52) U.S. Cl. CPC H01L 23/06; H01L 21/4803; H01L 21/4817; H01L 23/053

(57) ABSTRACT

An packaged integrated circuit device comprises a substrate having a top surface and a bottom surface; a die mounted on the top surface of the substrate; a lid comprising a central area and a peripheral area; wherein the central area comprises an deformable film above the die and the peripheral area is attached to the top surface of the substrate, and wherein the deformable film in the central area is concave towards the substrate. Corresponding manufacturing methods are also disclosed.

### BACKGROUND

The present invention relates to integrated circuit (IC) device packaging, and more particularly to a lid to be attached to a package substrate for packaging an integrated circuit (IC) device.

FIG. 1A shows cross-sectional side view of a conventional IC package 100. FIG. 1B shows a top view of the conventional IC package 100 with lid removed. The IC package 100 includes a substrate 102 with bottom surface 104 and top surface 106. A conventional metal lid 108, consisting of a top portion 110, a side wall 112 and an end portion 114. The lid 108 is attached to the top surface 106 of the substrate 102 by a bonding layer 120. A semiconductor die 116 is mounted on the substrate 102. The bonding layer 120 is not continuous and the IC package 100 has some gaps 118 between end portion 114 of the lid 108 and the substrate 108 to allow gases to escape during package assembly and assembly or mounting of the packaged IC onto a printed circuit board (not shown), which is typically achieved by a solder reflow type of process.

However, outside moisture is also able to penetrate into the internal atmosphere of the package 100 through these gaps 118. For example, after the lid 108 attached onto one side of the substrate, the solder ball (not shown) will be then attached on the bottom side 104 of the substrate 102, and then there is a water-clean process to remove the flux used in the solder ball attach process. Water may get into the package because of the gaps 118. The moisture inside the IC package 100 will downgrade the reliability level of the package.

Thus, it would be desirable to have an integrated circuit package, which provides a substantially hermetic environment to prevent water getting into the package and relieve air pressure of the package.

### SUMMARY

This summary is provided to introduce a selection of concepts in a simplified form that are further described below in the Detailed Description. This summary is not intended to be relied on to identify key features or essential features of the claimed subject matter, nor is it intended to be used to limit the scope of the claimed subject matter.

According to one inspect of the invention, there is An integrated circuit device package with a lid comprising a substrate having a top surface and a bottom surface; a die mounted on the top surface of the substrate; a lid comprising a central area and a periphery area; wherein the central area comprises an deformable film above the die and the periphery area is attached to the top surface of the substrate, and wherein the deformable film in the central area comprises a downward arc shaped film.

According to one or more embodiments, the film is a plastic film.

According to one or more embodiments, the film is printed with a layer of metal.

According to one or more embodiments, the metal is Tin.

According to one or more embodiments, the periphery area comprises a top rim connected to the film and a side wall connected to the top rim.

According to one or more embodiments, the angle of the side wall from the horizontal is between 30 degree to 90 degree.

According to one or more embodiments, the side wall is a vertical wall.

According to one or more embodiments, the periphery area comprises an end portion attached to the top surface of the substrate.

According to one or more embodiments, the end portion has two ends, and wherein the ends of the end portion proximate to the die connects to the side wall.

According to one or more embodiments, the end portion has two ends, and wherein the end of the end portion proximate to the die connects to the side wall.

According to one or more embodiments, the end portion has two ends, and wherein the distal end of the end portion far away from the die connects to the side wall.

According to one or more embodiments, the side wall is attached to the top surface of the substrate.

According to one or more embodiments, the die comprises a flip chip.

According to a second inspect of the invention, there is a lid for attaching to a package substrate, comprising a central area and; periphery area around the central area; wherein the central area comprises an deformable film above the die and the periphery area is attached to the top surface of the substrate, and wherein the deformable film in the central area comprises a downward arc shaped film.

According to one or more embodiments, the film is a plastic film.

According to one or more embodiments, the film is printed with a layer of metal.

According to one or more embodiments, the metal is Tin.

According to one or more embodiments, the periphery area comprises a top rim connected to the film, a side wall connected to the top rim and an end portion connected to the side wall, wherein the end portion of the periphery area is attached to the package substrate.

According to a third inspect of the invention, there is a method of making a lid for attaching to a package substrate, comprising: providing a metal ring; providing an deformable film; laminating the metal ring with the deformable film to form a film-metal ring; punching the film-metal ring to form a lid with a central area and a periphery area, wherein the central area comprises the deformable film above the die and the periphery area is attached to the substrate, and wherein forming the lid comprises forming a downward arc shaped film in the central area.

According to one or more embodiments, the method further comprises printing the deformable film in the central area with a layer of metal.

### BRIEF DESCRIPTION OF THE DRAWINGS

So that the manner in which the above recited features of the present application can be understood in detail, a more particular description of the application, briefly summarized above, can be had by reference to embodiments, some of which are illustrated in the appended drawings. It is to be noted, however, that the appended drawings illustrate only typical embodiments of this application and are therefore not to be considered limiting of its scope, for the application can admit to other equally effective embodiments. The drawings are for facilitating an understanding of the application and thus are not necessarily drawn to scale. Advantages of the subject matter claimed will become apparent to those skilled in the art upon reading this description in conjunction with the accompanying drawings, in which like reference numerals have been used to designate like elements, and in which:

FIG. 1A is a cross-sectional side view of a conventional IC package;

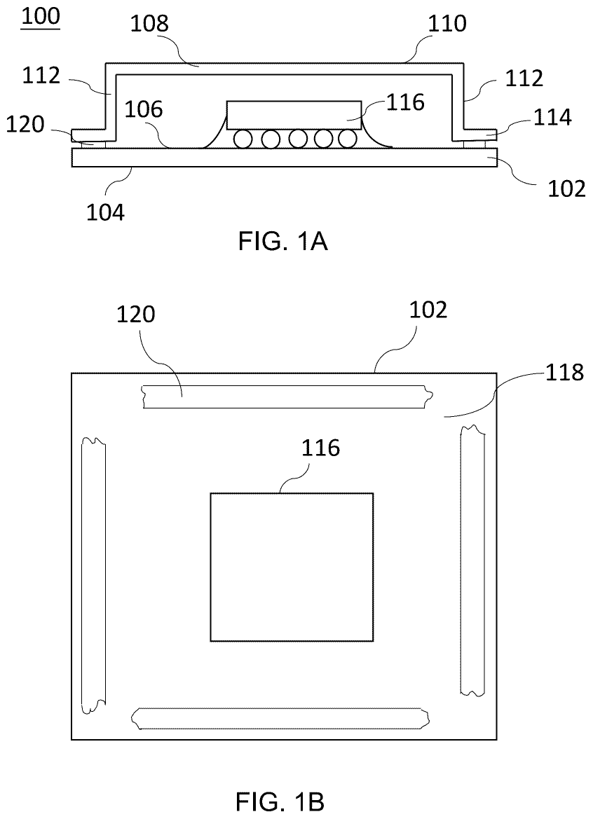

FIG. 1B is a top plan view of the conventional IC package with lid removed;

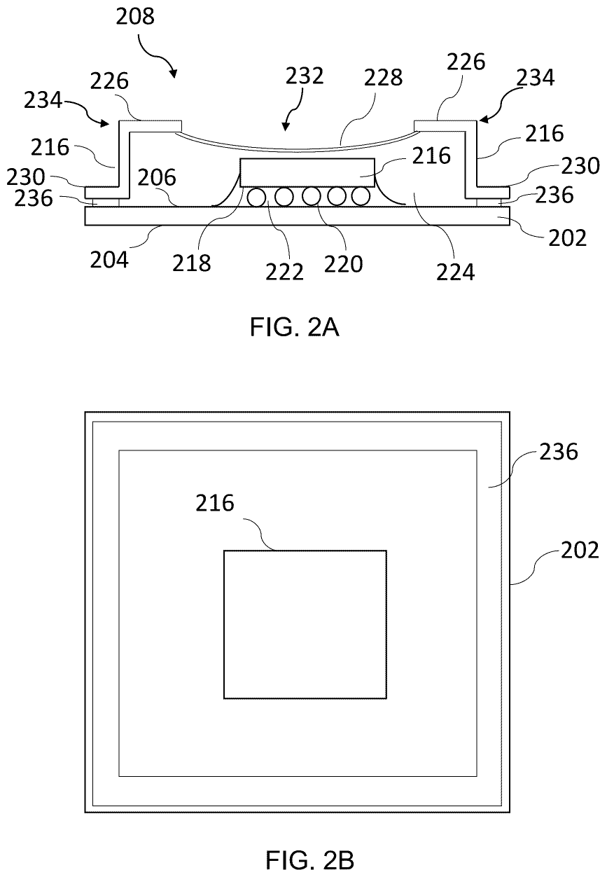

FIG. 2A is a cross-sectional side view of an IC package in accordance with one embodiment of the invention;

FIG. 2B is a top plan view of the IC package in accordance with one embodiment of the invention with lid removed;

FIG. 3A-FIG. 6B show the main steps in the manufacturing process of making the lid;

FIG. 7 is an example flow chart sequence depicting a process of making a lid in accordance with one embodiment of the present invention;

FIG. 8 is an example flow chart sequence depicting a process of fabricating a lid package in accordance with one embodiment of the present invention.

### DETAILED DESCRIPTION

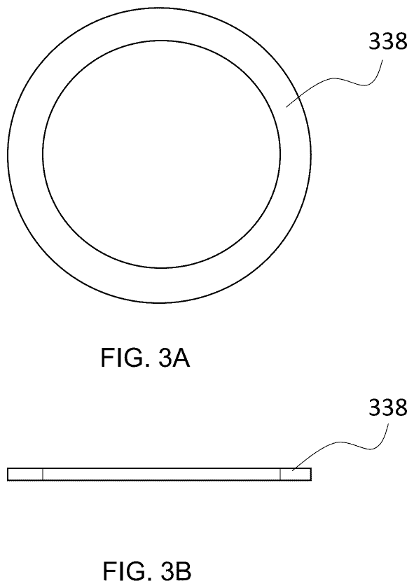

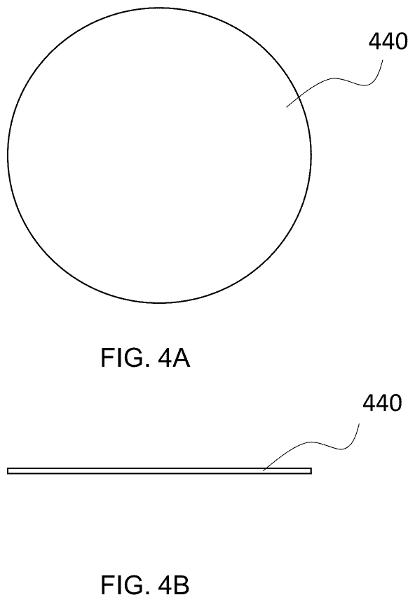

FIG. 2A shows cross-sectional side view of an IC package 200 in accordance with one embodiment of the invention. FIG. 2B shows a top plan view of the IC package 200 with lid removed. The IC package 200 includes a substrate 202 with bottom surface 204 and top surface 206. Typically the substrate comprises a rectangular shape for a rectangular shaped device. Package contacts (not shown) are disposed on the bottom surface 204. The package contacts can comprise spherical shaped structures or balls arranged in a grid pattern to form a ball grid array (BGA). The balls, for example, comprise solder. Various types of solders can be used, such as lead-based, non-lead based alloys or conductive polymers. The package contacts may be arranged in other patterns or other types of package contacts can be used.

A semiconductor die 216 is mounted on the top surface 206 of the substrate 202. The die can be any type of IC. For example, the IC can be a memory device such as a dynamic random access memory (DRAM), a static random access memory (SRAM), a digital signal processor (DSP), a microcontroller, a system-on-chip, as well as other types of devices. The die 216 is connected to the substrate by a wire bonding or tape-automated bonding.

In some embodiments, the die 216 is in the form of a flip chip. In the flip chip configuration, the die 216 is oriented with an active surface 218 facing down towards the substrate 202. Conductive bumps 220 are arranged on the active surface 218 of the die 216 to attach the die to the upper surface 206 of the substrate 202. The conductive bumps, for example, comprise solder bumps. Various types of solders, such as lead-based, non-lead-based alloys or conductive polymers, can be used to form the conductive bumps. Die contact pads (not shown) are disposed on the top surface of the substrate. The die contact pads are connected to the package contacts by conductive traces (not shown). When the die is mounted onto the substrate, the bumps are mated to the die contact pads. The solder paste melts during assembly, forming a connection between the pads and conductive bumps of the die in a reflow process.

An under fill 222, such as epoxy, can be provided under the die to encapsulate the conductive bumps and improve the reliability. Various techniques can be used to provide the underfill in the cavity. The underfill, for example, can be needle-dispensed along the edges of the chip and drawn into the space between the die and substrate by capillary action and cure to form a permanent bond. Other techniques such as moldable underfill for applying the underfill can also be used.

A lid 208 is provided to comprise a central area 232 and a peripheral area 234. The central area 232 comprises a film 228. The film 228 is deformable, or elastic. As, shown, in a normal state or configuration, the film 228 in the central area 232 is generally downward arc shaped towards the substrate 202, in that, at room temperature, the centre of the film is deformed inwards, or downwards, towards the die. That is to say it is concave. The peripheral area 234 comprises a top rim 226 attached to the film 228, a side wall 216 connected to the rim 228 and an perimeter edges or end portion 230 connected to the side wall 216. FIG. 2 does not show how the film is attached to the rim—this will be discussed in more detail hereinbelow. The peripheral area of the lid, is typically generally, or substantially, metallic. N particular, the top rim 226, the side wall 216 and the end portion 230 may be composed of a high thermal conductivity material, such as Tin, copper, aluminum, or a metal matrix composite. In one embodiment, the side wall 216 is a vertical wall. In other embodiments, the sidewall is sloping, such that the angle of the side wall 216 from the horizontal may be between 30 degree to 90 degree.

Conventional lids are generally homogenous structures, or composed of a single material, such as Tin, copper or the like. According to the embodiments of the present disclosure, the film 228 of the lid 208 is composed of a material which is different from the material of the rim and the side wall of the lid. In a preferred embodiment, the material is one of the class of materials which are generically referred to as “plastic” or “plastics”. In particular, the material may be PO, EVA, PET etc., and the thickness of the film 228 may be in a range of 5 μm˜20 μm. The film 228 may be printed, with or otherwise covered, coated, or protected by a very thin thickness of a metal material (typically in the range of 1-5 μm) to mitigate the damage from the outside environment. The metallic coating may be either on the outer surface of the film (ie that surface further from the die), or the inner surface, or both. In one embodiment, the printed material is Tin because Tin has a good elastic character.

As will be discussed in more detail hereinbelow, the film 228 is attached (not shown in FIG. 2) to the inner surface of the rim 228 to form, under normal conditions such as room temperature and atmospheric pressure, an arc shaped, or concave, film forming the center of the lid 208. The film is downwards concave. This may be in part due to the weight of the film and may be in part due to the pre-molding of the film into the concave configuration. During the solder reflow process, the film deforms upwards, and in particular it may “pop-up” upward when the air pressure increases inside the package. The upwards deformation, or even pop-up of the film generally acts to relieve the air pressure inside the package which may also mitigate the damage on the substrate. In some embodiments, the film 228 is only attached to the inner surface of the rim 228. The skilled person will appreciate that in some other embodiments, the film 228 is attached to the inner surface of the rim 228, the side wall 216 and the end portion 230. The film attached to the rim or the side wall or the end portion is not shown in FIG. 2A.

The end portion 230 of the lid 208 is bonded to the substrate 202 via a bonding layer 236. The bonding layer 236 is typically an adhesive layer. As shown in FIG. 2B, the bonding layer 236 is continuous. That is to say, it does not have gaps therearound. The perimeter edges, or end portion 230, of the lid 208 contact the bonding layer 236 on the upper surface of the substrate 202, thereby forming a substantially sealed cavity 224 around the die such that there is no air-gap between the perimeter of the lid 224 and the substrate 202. The lid can be of any shape so long as it can be properly adapted to engage the cavity of the IC package. The connection between the lid and the substrate without gaps provides a hermetic environment, or one that is substantially hermetic, which prevents outside water, moisture, or other fluid, getting into the package during a flux-clean post-solder ball reflow process. The upwards deformation of the film may relieve the thermal pressure inside the package during the heating in the solder reflow process because the film deformation can expand the inner room to relieve the air pressure.

It should be noted that, as used herein, the term “package” includes the substrate and the lid whereas the term “packaged integrated circuit (IC) device” includes both the package with all its constituent components as well as the die mounted within the package.

The lid 208 of the preferred embodiments may be formed by any one of several methods. The following describes the details of a method for manufacturing the lid according to one or more embodiments of the invention. The process for manufacturing the lid can use several steps including blanking, coining, piercing, deburring, cleaning, plating, inspection, lamination and punching. The steps, in sum, transform raw material taken from separate sources, such as a Tin coil and a film, into a finished part. One or more of these steps, such as the cleaning and inspection steps, can be repeated during the course of the manufacturing process. Although Tin coils or strips are referenced as raw material in this process description, it should be understood that another suitable heat-conductive material can be substituted for Tin.

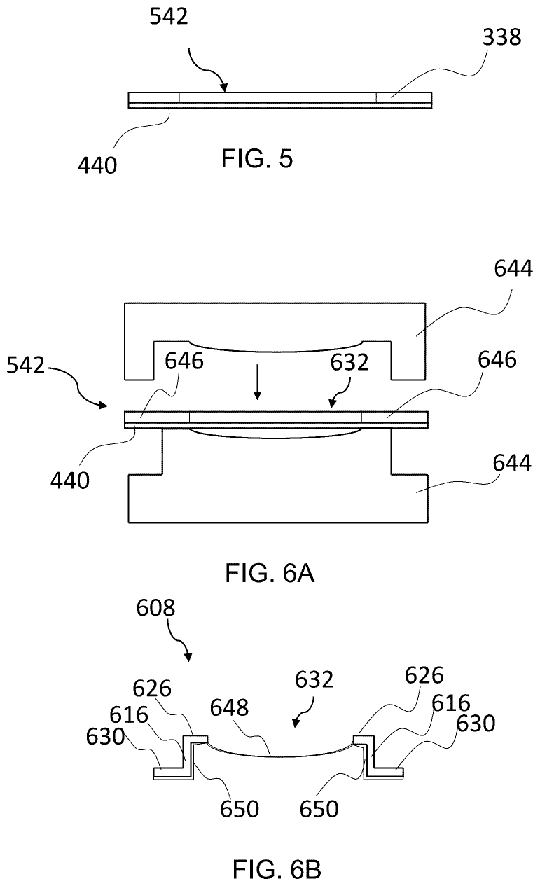

Referring to FIG. 3A and FIG. 3B, a first main step in the manufacturing process of making the lid may be to form a metal frame, such as the ring shown, from a metal strip. FIG. 3A shows the top plan view of the metal ring 338, and FIG. 3B shows the side view of the metal ring 338. This first main step can be accomplished using an etching process or a punch process to form a metal ring 338. In other embodiments, the metal frame can be formed in other shapes, such as rectangular shape with a cavity in the center.

Referring to FIG. 4A and FIG. 4B, the second main step of the manufacturing process of making the lid is to form an appropriately-shaped film. FIG. 4A shows the top plan view of the film 440, and FIG. 4B shows the side view of the film 440. The film 440 is a film of a plastics material. This second step can be accomplished using, for example, a punch process, to result in a ring as shown, or another shape (such as a rectangle for a rectangular-shaped lid).

Referring to FIG. 5, the third main step of the manufacturing process of making the lid is to laminate the metal ring 338 with the plastic film 440 to form a film-metal ring 542 by attaching the film 338 onto the metal ring 440 firmly. This third step can be accomplished using a punch process or a cure process. The skilled person will appreciate that in the embodiment shown in FIG. 5, the outer perimeter of the film 440 aligns with the perimeter of the metal frame or ring 338. However, according to other embodiments horizontal size of the film 440 may be smaller than the size of the outer area of the metal frame or ring 338 but bigger than the area of hole or annulus in the metal frame or ring 338, to ensure there is at least a partial overlap of the components, to allow for a bond therebetween.

Referring to FIG. 6A and FIG. 6B, the fourth main step of manufacturing process of making the lid is to punch or press the film-metal assembly thereby deforming it to form a lid 608 with a concave film in the center. This fourth step can be accomplished using a pressing process. FIG. 6A shows a side view of the film-metal ring of forming the lid by a molding tool or press, at which time the molding tool 644 has been partially closed, such that the lower part of the press-tool (also referred to as a stationary ram) is in contact with the film-metal ring 542. FIG. 6B is a side view showing a lid after deformation. As shown in FIG. 6A, 6B, by using a press 644, a deformation between the metal part 646 and the film part 440 in the vertical direction is formed. As illustrated in FIG. 6A and FIG. 6B, according to one or more embodiments, the metal part 646 is pressed down and formed a rim 626, a side wall 616 and an perimeter edges or end portion 630, the film 440 in the center arear 632 of the film-metal ring 542 is pressed downward to form a concave film 648, and the film 440 attached to the metal part 646 is pressed to form part 650. The skilled person will appreciate that in the embodiment shown in FIG. 6 B, the metal part 646 is pressed to form a rim, a side wall and an end portion which is extend outward from the side wall. However, according to other embodiments, metal part 646 may be pressed to only form a rim 626 and a side wall. Furthermore, according to other embodiments the metal part 646 may be pressed to form a rim, a side wall and an end portion which is extend inward from the side wall.

The fifth main step of manufacturing process of making the lid is to deburr, clean, and dry the lids. Following these steps, the lid in the shape of an open box in then positioned open side down over the substrate. The lid may be bonded to a semiconductor substrate by an adhesive layer. The adhesive layer may be placed on some part of the lid, or on the substrate, or on both, to facilitate bonding to the substrate of the package.

At room temperature, the film bends downward. As temperature increases, the film deforms up or pops up to reduce the pressure within the cavity formed between the lid and the substrate, thereby providing stress relief, resulting in a lower mechanical load on the bond between the lid and the substrate. This reduce the chance of mechanical failure while there are no gaps between the lid and the substrate.

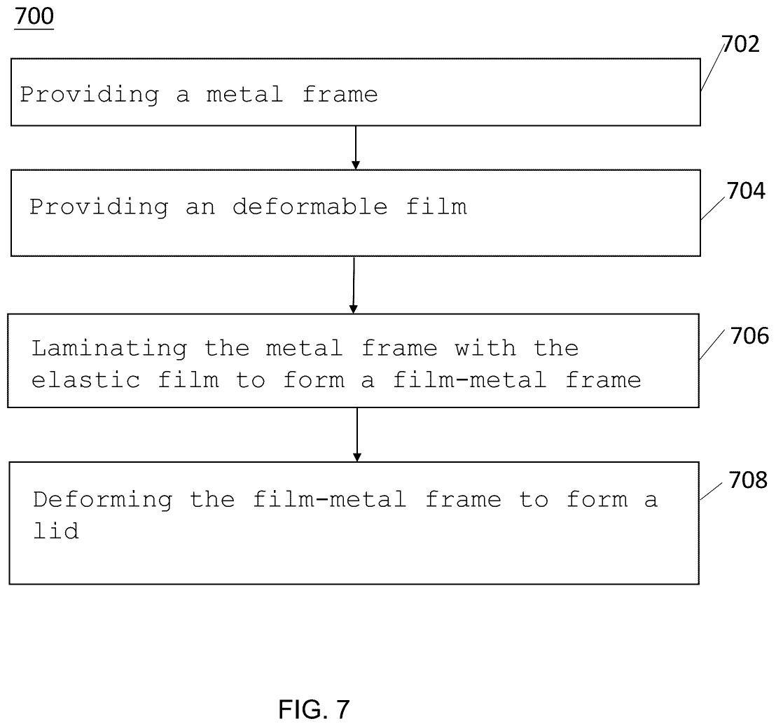

Turning now to FIG. 7, there is illustrated an example flow chart sequence 700 depicting a process of fabricating making a lid for attaching to a package substrate. The process begins at step 702 by providing a metal frame. At step 704, provide an deformable film. At step 706, laminate the metal frame with the elastic film to form a film-metal frame. At step 708, deform the film-metal frame to form a lid with a central area and a peripheral area. The central area comprises the deformable film above the die and the peripheral area is attached to the substrate. Forming the lid comprises forming a downwards concave film in the central area.

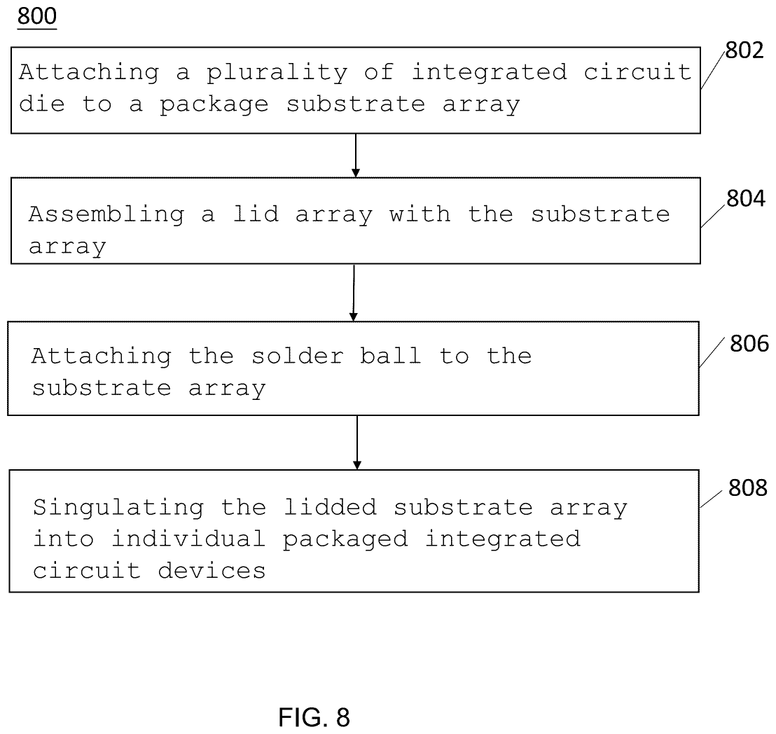

Turning now to FIG. 8, there is illustrated an example flow chart sequence 800 depicting a process of fabricating a lidded package in accordance with one embodiment of the present invention. The process begins at step 802 when a substrate array is assembled by attaching a plurality of integrated circuit die in an array or matrix pattern using flip-chip attach methods to a package substrate array. At step 804, a lid array having a plurality of lids is assembled in registry with the substrate array. At step 806, solder ball conductors may be attached to the substrate. Finally, at step 708, the lidded substrate array may be singulated into individual packaged integrated circuit devices, such as by using saw singulation.

The use of the terms “a” and “an” and “the” and similar referents in the context of describing the subject matter (particularly in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. Furthermore, the foregoing description is for the purpose of illustration only, and not for the purpose of limitation, as the scope of protection sought is defined by the claims as set forth hereinafter together with any equivalents thereof entitled to. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the application as claimed.

Preferred embodiments are described herein, including the best mode known to the inventor for carrying out the claimed subject matter. Of course, variations of those preferred embodiments will become apparent to those of ordinary skill in the art upon reading the foregoing description. The inventor expects skilled artisans to employ such variations as appropriate, and the inventor intends for the claimed subject matter to be practiced otherwise than as specifically described herein. Accordingly, this claimed subject matter includes all modifications and equivalents of the subject matter recited in the claims appended hereto as permitted by applicable law. Moreover, any combination of the above-described elements in all possible variations thereof is encompassed unless otherwise indicated herein or otherwise clearly contradicted by context.

1. A packaged integrated circuit device comprising:
a substrate having a top surface and a bottom surface;
a die mounted on the top surface of the substrate;
a lid comprising a central area and a peripheral area;
wherein the central area comprises an deformable film above the die and the peripheral area is attached to the top surface of the substrate, and wherein the deformable film in the central area is concave towards the substrate.

2. The packaged integrated circuit device of claim 1, wherein the film is a plastic film.

3. The packaged integrated circuit device of claim 1, wherein the film is coated with a layer of metal.

4. The packaged integrated circuit device of claim 1, wherein the metal is Tin.

5. The packaged integrated circuit device of claim 1, wherein the peripheral area comprises a top rim and a side wall connected to the top rim, wherein both the top rim and the side wall attached to the film.

6. The packaged integrated circuit device of claim 5, wherein the angle of the side wall from the horizontal is between 30 degree to 90 degree.

7. The packaged integrated circuit device of claim 5, wherein the side wall is a vertical wall.

8. The packaged integrated circuit device of claim 5, wherein the peripheral area comprises an end portion attached to the top surface of the substrate.

9. The packaged integrated circuit device of claim 8, wherein the end portion has two ends, and wherein the end of the end portion proximate to the die connects to the side wall.

10. The packaged integrated circuit package of claim 8, wherein the end portion has two ends, and wherein the distal end of the end portion far away from the die connects to the side wall.

11. The packaged integrated circuit device of claim 5, wherein the side wall is attached to the top surface of the substrate.

12. The packaged integrated circuit device of claim 1, wherein the die comprises a flip chip.

13. A lid for attaching to a package substrate, comprising a central area and;
peripheral area around the central area;
wherein the central area comprises an deformable film, and
wherein the deformable film in the central area is concave towards the substrate.

14. The lid of claim 1, wherein the film is a plastics film.

15. The lid of claim 1, wherein the film is coated with a layer of metal.

16. The lid of claim 1, wherein the metal is Tin.

17. The lid of claim 1, wherein the peripheral area comprises a top rim connected to the film, a side wall connected to the top rim and an end portion connected to the side wall, wherein the end portion of the peripheral area is configured to be attached to a package substrate.

18. A method of making a lid for attaching to a package substrate, comprising:
(a) providing a metal frame;
(b) providing an deformable film;
(c) laminating the metal frame with the deformable film to form a film-metal frame;
(d) deforming the film-metal frame to form a lid with a central area and a peripheral area, wherein the central area comprises the deformable film above the die and the peripheral area is attached to the substrate, and
wherein forming the lid comprises forming a downwards concave film in the central area.

19. The method of claim 18, further comprises coating the deformable film in the central area with a layer of metal.
